(19) United States
(12) Patent Application Publication
(10) Pub. No.: US 2019/0109300 A1
(43) Pub. Date: Apr. 11, 2019

(54) PLANARIZING HMDSO BUFFER LAYER WITH CHEMICAL VAPOR DEPOSITION

(71) Applicant: Applied Materials, Inc., Santa Clara, CA (US)

(72) Inventors: Helinda NOMINANDA, Santa Clara, CA (US); Jrjyan Jerry CHEN, Campbell, CA (US)

(21) Appl. No.: 15/729,440

(22) Filed: Oct. 10, 2017

(51) Int. Cl. H01L 51/56; H01L 51/52

(52) U.S. Cl. CPC H01L 51/56; H01L 51/5256

(57) ABSTRACT

Methods of forming a thin film encapsulation (TFE) structure over an organic light emitting diode (OLED) device are provided herein. In one embodiment, the method includes depositing a fluorinated plasma-polymerized hexmethyldisiloxane (PP-HMDSO:F) buffer layer over a patterned substrate. The (PP-HMDSO:F) buffer layer is formed using precursor gases comprising HMDSO, NF₃, N₂O, and N₂. The method provides for superior planarization and reduced particulate contamination than processes where the precursor gas comprises SiF₄.

### BACKGROUND

### Field

Embodiments described herein generally relate to thin film encapsulation (TFE) structures and, in particular, to methods of forming TFE structures for an organic light omitting diode (OLED) device.

### Description of the Related Art

TFE structures are commonly used in the manufacturing of OLED displays and flexible organic light emitting diode (FOLED) displays to surround, and thereby protect, an OLED device from degradation due to water and/or oxygen permeation thereinto.

Typically, TFE structures are formed of water and oxygen transport limiting transparent materials. One method of forming a TFE structure over an OLED device includes depositing a multilayer stack of at least alternating barrier layers and buffer layers, where each buffer layer is disposed between two barrier layers. The barrier layers are typically formed of transparent inorganic material(s), such as transparent dielectrics, having low water and oxygen permeability, for example silicon nitride. The buffer layer(s) are typically formed of a transparent polymerized organosilicon, such as a fluorinated plasma-polymerized hexmethyldisiloxane (PP-HMDSO:F). The buffer layer at least provides a planarizing layer over the underlying surface topography and/or irregularities in the previously deposited barrier layer, increases the permeation channel length between voids in the barrier layers, and decouples intrinsic defects found in, on, or through the barrier layers. Achieving a buffer layer that meets the above objectives has proven difficult.

Accordingly, what is needed in the art are buffer layers having improved planarization and methods of depositing buffer layers that reduce particulate contaminates associated therewith.

### SUMMARY

Embodiments of the present disclosure generally relate to TFE structures and methods of manufacturing thereof. More specifically, embodiments of the present disclosure relate to methods of forming planarizing fluorinated plasma-polymerized hexmethyldisiloxane (PP-HMDSO:F) buffer layers and the TFE structures thereformed.

In one embodiment, a method of forming an organic buffer layer is provided. The method includes flowing processing gases into a processing volume of a processing chamber, forming a plasma of the processing gases, and depositing the organic buffer layer on a patterned substrate, where the organic buffer layer comprises the reaction product of the processing gases. Herein, the processing gases comprise a polymer precursor, a fluorine precursor comprising NF₃, N₂, and an inorganic oxygen precursor.

In another embodiment, a method of forming a TFE layer is provided. The method includes positioning a patterned substrate in a processing volume of a processing chamber, flowing processing gases into the processing volume, forming a plasma of the processing gases, and depositing a polymerized organic layer on the patterned substrate. Herein, the patterned substrate comprises an active stack disposed on a substrate and a first barrier layer disposed thereover. The first barrier layer comprises a recessed region and an elevated region and a step height from the recessed region to the elevated region is between about 1 μm and about 4 μm. The processing gases comprise a polymer precursor comprising hexamethyldisiloxane (HMDSO), a non-silicon containing fluorine precursor comprising NF₃, N₂, and an inorganic oxygen precursor comprising N₂O.

In another embodiment, a method of forming a TFE structure is provided. The method includes depositing a first dielectric barrier layer on a patterned substrate. The patterned substrate herein comprises an OLED formed on a rigid or flexible sheet. The deposited first dielectric barrier layer herein has a first thickness between about 500 Å and about 2 μm, comprises a recessed region and an elevated region, and has a step height from the recessed region to the elevated region between about 1 μm and about 4 μm.

The method further includes depositing a polymerized organic buffer layer over the first dielectric barrier layer. Depositing the polymerized organic buffer layer includes positioning the patterned substrate in a processing volume of a processing chamber, the patterned substrate having the first barrier layer deposited thereon, flowing processing gases into the processing volume, the processing gases comprising hexamethyldisiloxane (HMDSO), a fluorine precursor consisting of NF₃, N₂, and an inorganic oxygen precursor consisting of N₂O, forming a plasma of the processing gases, and depositing the polymerized organic buffer layer. The deposited polymerized organic buffer layer herein has a second thickness between about 0.5 μm and about 5 μm.

The method further includes depositing a second dielectric barrier layer, having a third thickness between about 500 Å and about 2 μm, over the deposited polymerized organic buffer layer to form the TFE structure. Herein, the TFE structure comprises at least the first dielectric barrier layer, the polymerized organic buffer layer, and the second dielectric barrier layer, and has a conformal factor (CF) of less than about 0.35.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross-sectional representation of a portion of an OLED device, formed according to embodiments described herein.

FIG. 2 is a schematic cross-sectional view of an example PECVD chamber, used to practice the methods described herein.

FIG. 3 is a flowchart illustrating a method of forming an organic buffer layer, according to one embodiment.

FIGS. 4A-4C are schematic sectional cross-sectional views that illustrate the formation of an OLED device using the method of FIG. 3.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure generally relate to TFE structures and methods of manufacturing thereof. More specifically, embodiments of the present disclosure relate to methods of forming planarizing fluorinated plasma-polymerized hexmethyldisiloxane (PP-HMDSO:F) buffer layers and the TFE structures thereformed.

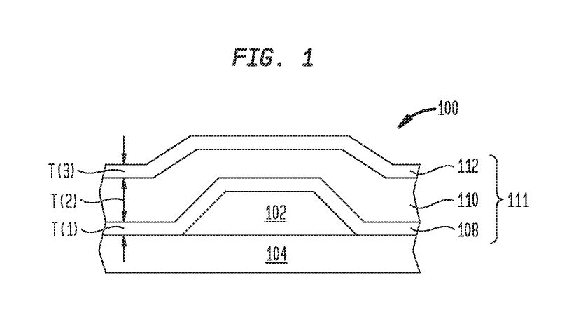

FIG. 1 shows an organic light-emitting diode (OLED) device 100 including a TFE structure 111, formed according to embodiments described herein. The OLED device 100 includes a substrate 104 having an OLED 102, formed from a series of deposition and etching processes, disposed thereon. The substrate 104 may be rigid or flexible and is typically formed of a glass, metal, or plastic sheet. In some embodiments, the substrate 104 comprises a thin flexible polymer sheet, such as a polyethyleneterephthalate (PET) sheet or a polyethyleneterephthalate (PEN) sheet. In some embodiments, the thin flexible polymer sheet is disposed on a rigid glass, metal, or plastic base to facilitate handling of the substrate 104 during manufacturing processes. Herein, a thin film encapsulation TFE structure 111 is disposed over the OLED 102 to protect the OLED device 100 from performance degradation due to moisture and oxygen ingress thereinto. As shown, the TFE structure 111 includes a first barrier layer 108, a second barrier layer 112, and a buffer layer 110 disposed therebetween. In some embodiments, the TFE structure comprises a plurality of barrier layers and buffer layers where each buffer layer is disposed between two barrier layers. Typically, the OLED device 100 herein further includes a contact layer (not shown) disposed between the OLED 102 and the substrate 104 where the contact layer comprises a transparent conductive oxide such as indium tin oxide, indium zinc oxide, zinc oxide, or tin oxide.

The barrier layers 108, 112 typically have a thickness T(1), T(3) of between about 500 Å and about 2 μm, such as between about 500 Å and about 2 μm, for example about 1 μm. Herein, the barrier layers 108, 112 are formed of a transparent dielectric film such as silicon nitride (SiN), silicon oxynitride (SiON), silicon dioxide (SiO₂), aluminum oxide (Al₂O₃), aluminum nitride (AlN), titanium oxide (TiO₂), zirconium (IV) oxide (ZrO₂), aluminum titanium oxide (AlTiO), aluminum zirconium oxide (AlZrO), zinc oxide (ZnO), indium tin oxide (ITO), AlON, or combinations thereof.

The organic buffer layer 110, disposed between the barrier layers 108, 112, is typically formed of an polymeralized organic material, such as plasma polymerized hexamethyldisiloxane (HMDSO), for example fluorinated plasma-polymerized HMDSO (pp-HMDSO:F) and/or a polymer material composed of hydrocarbons where the polymer material has a formula CₓH_{y}O_{z}, wherein x, y and z are integers. In other embodiments, the organic buffer layer 110 is formed of a material selected from a group consisting of polyacrylate, parylene, polyimides, polytetrafluoroethylene, copolymer of fluorinated ethylene propylene, perfluoroalkoxy copolymer resin, copolymer of ethylene and tetrafluoroethylene, parylene, and combinations thereof. Herein, the organic buffer layer 110 or at least one organic buffer layer of a plurality of buffer layers is formed of a fluorinated plasma-polymerized HMDSO (pp-HMDSO:F) deposited according to the methods described in this disclosure.

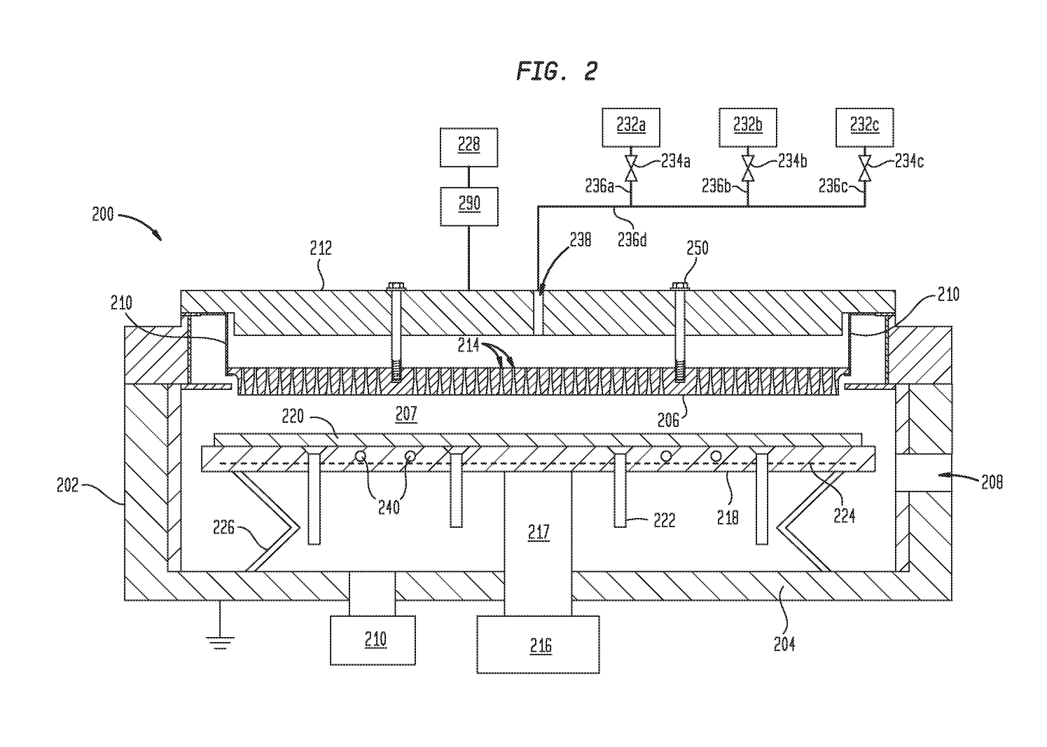

FIG. 2 is a schematic cross-sectional view of an example processing chamber, herein a plasma enhanced chemical vapor deposition chamber (PECVD chamber), used to practice the methods described herein. In this embodiment, the processing chamber 200 comprises a capacitively coupled plasma (CCP) source configured to ignite and maintain a plasma from processing gases through capacitive coupling therewith. In other embodiments, a processing chamber configured to comprise an inductively coupled plasma (ICP) source or a microwave plasma source, such as an electron cyclotron resonance plasma (ECR) source or a linear microwave plasma source (LPS) may be used. Typically, the CCP source and the ICP source are coupled to an RF power supply or a VHF power supply and the microwave plasma sources are coupled to a microwave power supply.

The processing chamber 200 includes a chamber body comprising one or more sidewalls 202, a chamber lid comprising a backing place 212, and a chamber bottom 204, which define a processing volume 207, and further includes a plasma generator, such as the gas distributor 206 coupled to the RF power supply 228. Typically, the RF power from the RF power supply 228 is delivered through an RF matching circuit 290. Herein, the gas distributor 206, which has a plurality of openings 214 disposed therethrough, is coupled to and/or supported from the backing plate 212 by a plurality of fasteners 250 and a suspension element 234, herein a flexible metal skirt. The gas distributor 206 uniformly distributes processing gases from a gas inlet 238 into the processing volume 207 and a plasma is formed from the processing gases between the gas distributor 206 and a substrate 220 disposed on a substrate support 218. During processing, the substrate 220 is typically spaced apart from the gas distributer by between about 200 mil and about 2000 mil, for example about 600 mil.

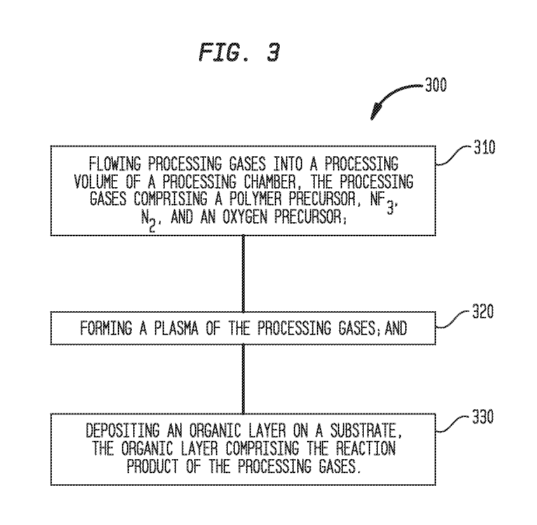

Herein, the gas inlet 238 is fluidly coupled to a primary gas conduit 236d which is fluidly coupled to a plurality of gas supplies 232a-c where a flowrate from each gas supply is regulated using a respective valve of a plurality of valves 234a-c. The plurality of valves 234a-c are typically located near the gas inlet 238 to prevent undesirable premature reaction of precursor gases in the primary gas conduit 236d. Nonetheless, precursor gas mixing, and undesirable premature reactions, in the dead space of minor conduits 236a-c when a valve from a respective plurality of valves 234a-c is closed is difficult to avoid. For example, in a case where a fluorine containing precursor gas comprising SiF₄ reacts with an inorganic oxygen precursor in the minor conduits 236a-c solid particles, such as SiO₂, are produced by the reaction. These solid particles lead to particulate contamination in the processing chamber and contribute to particulate contamination on the substrate and in the layers being deposited thereon. Undesirable particulate contamination in the processing chamber necessitates frequent maintenance and cleaning thereof and particulate contamination on the substrate suppresses device yield and/or the effectiveness of the deposited encapsulation layers against water and/or oxygen permeation. In contrast, the methods described herein, such as the method 300 described in FIG. 3, use a non-silicon containing fluorine precursor, such as NF₃, that will not produce solid silicon containing particles, such as SiO₂, upon reaction with the inorganic oxygen containing precursors.

Typically, the processing volume 207 is fluidly coupled to a vacuum 210, such as one or more dedicated vacuum pumps, that maintains the processing volume 207 at sub-atmospheric conditions and evacuates processing and other gases therefrom. A substrate support 218 disposed in the processing volume 207 includes a support shaft 217, sealingly extending through the chamber bottom 204, which is coupled to an actuator 216 that raises and lowers the support shaft 217, and the substrate support 218 disposed thereon, to facilitate transfer of the substrate 220 to and from the processing chamber 200. Herein, the substrate support 218 includes one or more resistive heating elements 224 and/or one or more cooling conduits 240 fluidly coupled to a coolant source (not shown) that are used to maintain the substrate support 218 and the substrate 220 disposed thereon at a desired temperature during the processing. Herein, one or more flexible RF return straps 226 electrically coupling substrate support 218 to the chamber bottom 204 provide an RF return path at the periphery of the substrate support 218. In some embodiments, the substrate support 218 further comprises an electrostatic chucking electrode (not shown) on or in the substrate support 218. In those embodiments, the electrostatic chucking electrode is typically coupled to a DC power supply which provides a potential between the substrate support 218 and the substrate 220 disposed thereon to create and electrostatic chucking force therebetween.

The substrate 220 is loaded into the processing volume 207 through an opening 208 in one of the side walls 202, which is conventionally sealed with a door or a valve (not shown) during deposition processes. A plurality of lift pins 222 are movably disposed through the substrate support 218 to facilitate transferring of the substrate 220 to and from the substrate support 218. When the substrate support 218 is in a lowered position the plurality of lift pins 222 extend above the surface of the substrate support 218 to lift the substrate 220 for access by a robot handler. When the substrate support 218 is in a raised processing position, the plurality of lift pins 222 are flush with, or below, the surface of the substrate support 218 and the substrate 220 rests directly on the substrate support 218 for processing. The lift pins 222 herein are moved (relative to the substrate support 218) by contact of their lower ends with a stationary or movable pin plate (not shown), or the bottom wall 204 of the processing chamber 200.

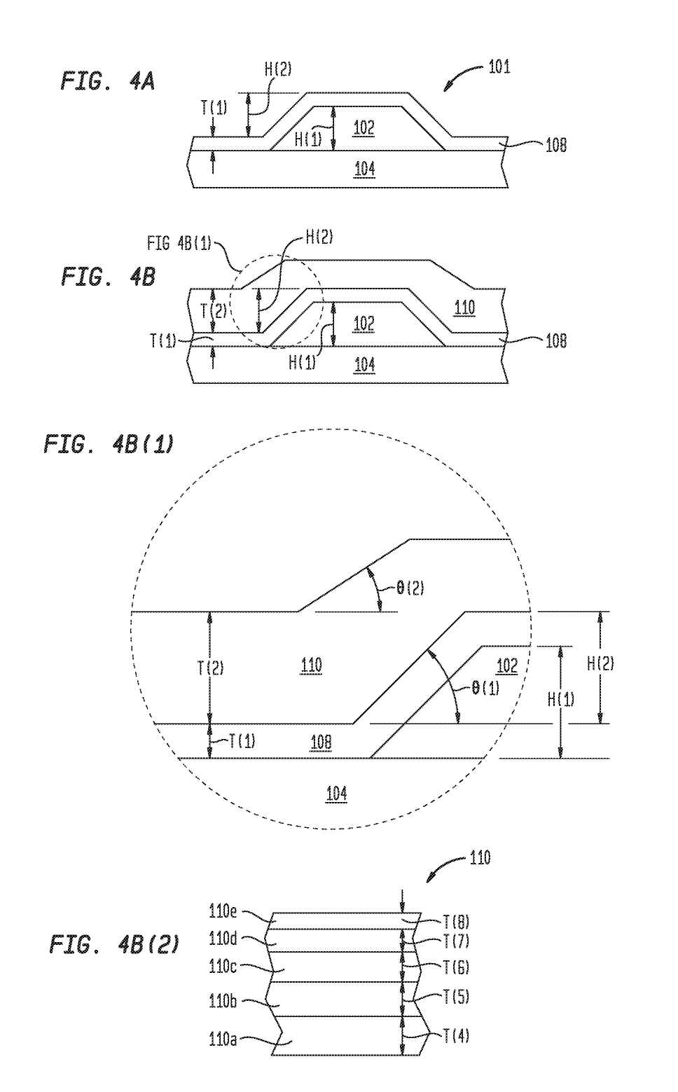

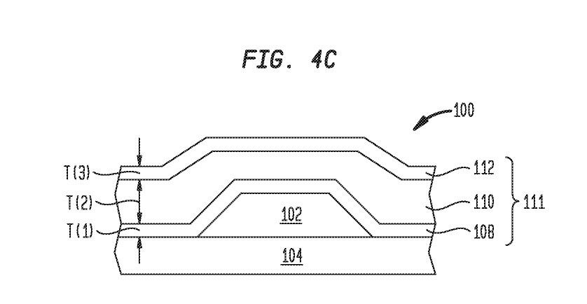

FIG. 3 is a flowchart illustrating a method 300 of forming an organic buffer layer, according to one embodiment. FIGS. 4A-4D illustrate the formation of an OLED device using the method of FIG. 3.

The method 300 includes flowing processing gases into a processing volume of a processing chamber at activity 310. Herein, the processing chamber is a PECVD processing chamber configured to ignite and maintain a plasma of the processing gases through capacitive coupling therewith, such as the processing chamber 200 shown in FIG. 2. The processing gases comprise a polymer precursor, a fluorine precursor comprising NF₃, an inorganic oxygen precursor comprising N₂O, and N₂. In some embodiments, the polymer precursor comprises hexamethyldisiloxane (HMDSO), and the inorganic oxygen precursor comprises N₂O. Herein, the fluorine precursor is a non-silicon containing fluorine precursor. In some embodiments, the fluorine precursor consists of NF₃ and the inorganic oxygen precursor consists of N₂O.

Flowrates of the processing gases into the processing volume are dependent on the size of a substrate to be processed and the chamber. For example, for a chamber sized to process a 400 mm by 500 mm substrate, the flowrate of the polymer precursor, such as HMDSO, is between about 50 sccm and about 1000 sccm, such as between about 100 sccm and about 500 sccm, for example about 240 sccm. The flowrate of the fluorine precursor is between about 10 sccm and about 100 sccm, such as between about 30 sccm and about 70 sccm, for example about 50 sccm. The flowrate of the inorganic oxygen precursor is between about 10 sccm and about 200 sccm, such as between about 100 sccm and 200 sccm, for example about 140 sccm. Typically, in the chamber configured to process a 400 mm by 500 mm substrate, the N₂ flowrate is between about 100 sccm and about 2000 sccm, such as between about 250 sccm and about 1250 sccm. In some embodiments, the N2 flowrate is incrementally increased from between about 250 sccm to about 1250 sccm during the deposition of the organic buffer layer 110.

Appropriate scaling should be used for chambers sized to process other sized substrates where a gas flow ratio of the polymer precursor to the fluorine precursor, (for example HMDSO:NF₃) is between about 5:1 and about 10:1, a gas flow ratio of the polymer precursor to the inorganic oxygen precursor, for example HMDSO:N₂O is between about 5:1 and 2.5, such as between about 1:1, and a gas flow ratio of the polymer precursor to N₂, for example HMDSO:N₂, is between about 10:1 and 1:10. Herein, a pressure in the processing volume 207 is maintained below about 4 Torr, such as below about 2 Torr, for example about 1600 mTorr.

The method 300 further includes forming a plasma of the processing gases at activity 320. Herein, forming the plasma comprises providing an RF power to a plasma electrode, such as the gas distributor 206 shown in FIG. 1. The RF power provided to the gas distributor is dependent on the size of the substrate and the chamber. For example, for a chamber sized to process a 400 mm by 500 mm substrate the RF power is between about 400 Watts and about 1000 Watts, such as between about 400 Watts and about 800 Watts, for example about 600 Watts, or between about 0.2 Watts/cm² (of substrate processing surface) and about 0.5 Watts/cm², such as between about 0.2 Watts/cm² and about 0.4 Watts/cm², for example about 0.3 cm².

The method 300 further includes activity 330 of depositing an organic layer, on a patterned substrate. FIGS. 4A-4C show a patterned substrate 101 and FIGS. 4B-4C show an organic buffer layer 110, formed according to the method 300, deposited thereon. In FIG. 4A the patterned substrate 101 includes a substrate 104 and an active stack, herein an OLED 102, disposed on the substrate 104 and extending from a surface thereof by a first height H(1) of between about 1 μm and about 4 μm, such as between about 2 μm and about 3 μm, or less than about 3 μm. Herein, the patterned substrate 101 further includes a first barrier layer 108 disposed over the OLED 102 and the substrate 104. Typically, the substrate 104 comprises a glass, metal, or plastic sheet and may be rigid or flexible. In some embodiments, the substrate comprises a thin flexible polymer sheet, such as apolyethyleneterephthalate (PET) or polyethyleneterephthalate (PEN) sheet. In some embodiments, the substrate is a rigid glass, metal, or plastic sheet with a thin flexible polymer sheet disposed thereon. Typically, a contact layer (not shown) is further disposed between the OLED 102 and the substrate 104 and comprises a transparent conductive oxide such as indium tin oxide, indium zinc oxide, zinc oxide, tin oxide, or combinations thereof.

The first barrier layer 108 shown in FIGS. 4A-4C comprises a dielectric film such as silicon nitride (SiN), silicon oxynitride (SiON), silicon dioxide (SiO₂), aluminum oxide (Al₂O₃), aluminum nitride (AlN), titanium oxide (TiO₂), zirconium (IV) oxide (ZrO₂), aluminum titanium oxide (AlTiO), aluminum zirconium oxide (AlZrO), zinc oxide (ZnO), indium tin oxide (ITO), AlON, or combinations thereof. The first barrier layer 108 herein has a first thickness T(1) of between about 500 Ang. and about 2 μm, such as about 1 μm. Typically, the first barrier layer 108 desirably conforms to the underlying surface, herein the substrate 104 and the OLED 102 disposed thereon, in order to provide uniform encapsulation of the OLED and any contaminate particles disposed thereon or proximate thereto. Therefore, the second height H(2), between an elevated region and a recessed region of the first barrier layer 108 is substantially the same as the first height H(1) of the OLED 102 disposed on the substrate 104. Further, the conformal factor (CF) of the first barrier layer 108 relative to the underlying surface is more than about 0.8, such as more than about 0.9. Herein, the CF of a layer is a ratio of the angle of a surface connecting an elevated surface and a recessed surface of the layer, relative to the recessed surface, and an angle of the underlying surface connecting the underlying elevated and recessed surfaces of the underlying layer(s), relative to the underlying recessed surface. Typically, a layer having a CF of 1 completely conforms to the underlying surfaces and a layer having a CF of 0 is flat.

Herein, the organic buffer layer 110 shown in FIGS. 4B-4C comprises the reaction product of the processing gases described in activity 310 of method 300, for example in some embodiments the organic buffer layer 110 comprises a fluorinated organosilicon material, such as a fluorinated plasma-polymerized hexmethyldisiloxane (PP-HMDSO:F) material. In some embodiments, the substrate is desirably maintained at a temperature below about 150° C., such as below about 100° C., for example between about 50° C. and about 100° C., such as about 80° C. during the deposition of the organic buffer layer 110.

Desirably, the organic buffer layer 110, deposited according to the method 300, provides a planarizing effect over the underlying surface where the organic buffer layer 110 has a CF (herein the ratio of θ(2) to θ(1)) of less than about 0.5, such as less than about 0.45, for example less than about 0.4, or less than about 0.35 for embodiments where the organic buffer layer 110 has a thickness T(2) of between about 0.5 μm and about 5 μm, such as between about 1 μm and about 3 μm and is deposited over a surface with a step height H(2). Herein, the desirably smaller CF value indicates that the organic buffer layer 110 is providing a more planarized surface when compared to an undesirable larger CF value, such as more than about 0.5 which would indicate an organic layer that is undesirably conforming to the underlying surface and/or any contaminate particles disposed therein, therethrough, thereon, or thereunder.

FIG. 4B(2) is a close up sectional view of a portion of the organic buffer layer 110 shown in FIGS. 4A-4B, according to one embodiment. As shown in FIG. 4B(2) the organic buffer layer 110 comprises a plurality of sub-layers 110a-e formed by incrementally increasing the N₂ flowrate during the deposition of the organic buffer layer 110. Table 1 shows a process used to form the sub-layers 110a-e of the organic buffer layer 110 shown in FIG. 4B(2) in a processing chamber configured to process a 400 mm by 500 mm substrate, according to one embodiment. In addition to the N₂ flowrates shown in Table 1, each of the sub-layers 110a-e were deposited by flowing 240 sccm of HMDSO, 140 sccm of N₂O, and 50 sccm of NF₃ into the processing volume of a processing chamber, such as processing chamber 200 described in FIG. 2. An RF power of about 600 Watts was provided to a gas distributor to ignite the processing gases into a processing plasma and the respective sub-layers 100a-e were deposited onto the patterned substrate 101 for the specified period of time to form the organic buffer layer 110. The substrate was spaced apart from the gas distributor by about 600 mil.

Incrementally increasing the N₂ flowrate during the deposition of the organic buffer layer 110 provides a higher organic content at the interface between the organic buffer layer and an underlying layer and lower organic content towards the upper surface (the surface distal to the aforementioned interface). Higher organic content provides a softer material that facilitates planarization and lower organic content provides a harder material more suitable as an interface for the subsequently deposited second barrier layer, shown in FIG. 4C. Herein, the relative thickness of the each of the sub-layers 110a-e shown in FIG. 4B(2) may be expressed as a ratio where T(4):T(5):T(6):T(7):T(8) is about 3:2:2:2:1 where thickness T(4) of the first sub-layer 110a, having the highest organic content and therefore softer, is about 3:1 to the thickness of the fifth (and last) sublayer 110e, which has the lowest organic content and is therefore harder.

TABLE 1

| Sub-Layer | N₂ | Time (s) | Thickness (μm) |
|---|---|---|---|
| 110a | 500 | 148 | 0.6 |
| 110b | 625 | 102 | 0.4 |
| 110c | 750 | 102 | 0.4 |
| 110d | 875 | 106 | 0.4 |
| 110e | 1000 | 56 | 0.2 |

In some embodiments, the method 300 further includes depositing a second barrier layer 112 on the organic buffer layer 110 to form a thin film encapsulation (TFE) structure 111 as shown in FIG. 4C. Herein, the TFE structure 111 comprises the first barrier layer 108, the organic buffer layer 110, and the second barrier layer 112 which has a thickness T(3) of between about 500 Å and about 2 μm, such as about 1 μm. In some embodiments, the TFE structure 111 has a conformal factor (CF) of less than about 0.40, such as less than about 0.35, or less than about 0.30.

The method described herein provide for the deposition of an organic buffer layer, comprising a fluorinated organosilicon material, used in a thin-film encapsulation structure. Embodiments described herein use NF₃, N₂O, and N₂ precursors in combination with a polymer precursor to provide an organic buffer layer having superior planarization properties and fewer related particulate contamination issues when compared to buffer layers formed using SiF₄.

While the foregoing is directed to embodiments of the present disclosure, other and further embodiments of the disclosure may be devised without departing from the basic scope thereof, and the scope thereof is determined by the claims that follow.

1. A method of processing a substrate, comprising:
flowing processing gases into a processing volume of a processing chamber, the processing gases comprising a polymer precursor, a fluorine precursor comprising NF₃, N₂, and an inorganic oxygen precursor;
forming a plasma of the processing gases; and
depositing an organic buffer layer comprising a reaction product of the processing gases on a patterned substrate, wherein the organic buffer layer has a conformal factor (CF) of less than about 0.5 and a thickness between about 0.5 μm and about 5 μm.

2. The method of claim 1, wherein the patterned substrate comprises an active stack disposed on a rigid or flexible substrate and a first barrier layer disposed thereover.

3. The method of claim 2, wherein the polymer precursor comprises hexamethyldisiloxane (HMDSO).

4. The method of claim 3, wherein the fluorine precursor consists of NF₃ and the inorganic oxygen precursor comprises N₂O.

5. The method of claim 4, wherein the inorganic oxygen precursor consists of N₂O.

6. The method of claim 5, wherein the first barrier layer comprises SiN.

7. The method of claim 6, wherein
the polymer precursor comprises hexamethyldisiloxane (HMDSO),
the fluorine precursor consists of NF₃, and
the inorganic oxygen precursor comprises N₂O.

8. (canceled)

9. The method of claim 7, wherein
a gas flow ratio of the polymer precursor to the fluorine precursor is maintained between about 10:1 and about 1:1.

10. The method of claim 9, wherein an N₂ flowrate is incrementally increased during the deposition of the organic buffer layer.

11. The method of claim 9, further comprising depositing a second barrier layer over the organic buffer layer.

12. The method of claim 11, wherein a TFE structure comprising the first barrier layer, the organic buffer layer, and the second barrier layer has a conformal factor of less than about 0.35.

13. The method of claim 9, wherein the active stack comprises an OLED.

14. A method of processing a substrate, comprising:
positioning a patterned substrate in a processing volume of a processing chamber, the patterned substrate comprising an active stack disposed on a substrate and a first barrier layer disposed thereover, wherein the first barrier layer comprises a recessed region and an elevated region, and wherein a step height from the recessed region to the elevated region is between about 1 μm and about 4 μm;
flowing processing gases into the processing volume, the processing gases comprising a polymer precursor comprising hexamethyldisiloxane (HMDSO), a non-silicon containing fluorine precursor comprising NF₃, N₂, and an inorganic oxygen precursor comprising N₂O;
forming a plasma of the processing gases; and
depositing a polymerized organic layer on the patterned substrate, wherein the polymerized organic layer has a conformal factor (CF) of less than about 0.5 and a thickness between about 0.5 μm and about 5 μm.

15. The method of claim 14, further comprising depositing a second barrier layer over the polymerized organic layer.

16. The method of claim 15, wherein the first barrier layer, the polymerized organic layer, and the second barrier layer comprise a thin film encapsulation (TFE) stack having a CF of less than about 0.35.

17. The method of claim 14, wherein a gas flow ratio of the polymer precursor to the fluorine precursor is maintained between about 10:1 and about 1:1.

18. The method of claim 17, wherein a flowrate of N₂ is incrementally increased during the deposition of the polymerized organic layer.

19. The method of claim 18, wherein the active stack comprises an OLED.

20. A method of processing a substrate, comprising:
depositing a first dielectric barrier layer on a patterned substrate, the patterned substrate comprising an OLED formed on a rigid or flexible sheet, wherein the deposited first dielectric barrier layer has a first thickness between about 500 Å and about 2 μm, comprises a recessed region and an elevated region, and has a step height from the recessed region to the elevated region between about 1 μm and about 4 μm;
depositing a polymerized organic buffer layer over the first dielectric barrier layer, comprising:
positioning the patterned substrate in a processing volume of a processing chamber, the patterned substrate having the first dielectric barrier layer deposited thereon;
flowing processing gases into the processing volume, the processing gases comprising hexamethyldisiloxane (HMDSO), a fluorine precursor consisting of NF₃, N₂, and an inorganic oxygen precursor consisting of N₂O;
forming a plasma of the processing gases; and
depositing the polymerized organic buffer layer, wherein the deposited polymerized organic buffer layer has a second thickness between about 0.5 μm and about 5 μm; and
depositing a second dielectric barrier layer, having a third thickness between about 500 Å and about 2 μm, over the deposited polymerized organic buffer layer to form a thin film encapsulation (TFE) structure, wherein the TFE structure comprises at least the first dielectric barrier layer, the polymerized organic buffer layer, and the second dielectric barrier layer, and wherein the TFE structure has a conformal factor (CF) of less than about 0.35.

21. The method of claim 1, wherein
the patterned substrate comprising an active stack disposed on a substrate and a first barrier layer disposed thereover,
the first barrier layer comprises a recessed region and an elevated region, and
a step height from the recessed region to the elevated region is between about 1 μm and about 4 μm.
